(19) United States
(12) Patent Application Publication
(10) Pub. No.: US 2008/0044258 A1
(43) Pub. Date: Feb. 21, 2008

(54) Fragile Member Processing System

(75) Inventor: Takeshi Akechi, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Lintec Corporation, Itabashi-ku, TOKYO (JP)

(21) Appl. No.: 11/791,481

(22) PCT Filed: Nov. 28, 2005
(86) PCT No.: PCT/JP05/21755

§ 371 Date: May 24, 2007

(30) Foreign Application Priority Data
Nov. 29, 2004 (JP) 2004-343736

(51) Int. Cl. H01L 21/683; B65H 1/00

(52) U.S. Cl. 414/217.1; 414/222.01

(57) ABSTRACT

A fragile member processing system is provided to perform a series of processes such that, after mounting a semiconductor wafer W to one surface of which a glass plate P has been stuck onto a ring frame RF, the glass plate P is peeled off to transfer/adhere the semiconductor wafer W, and the double-faced adhesive sheet S remaining on the surface of the semiconductor wafer W is peeled off. A transferring/adhering device 20 is provided so that, after forming a peeling initiation portion 62 between the glass plate P and the semiconductor wafer W, the angle thereof can be changed in the direction of erecting the ring frame RF. The present invention is also applicable to an object in which only a protective sheet is stuck to the circuit surface of the semiconductor wafer W. In this case, the transferring/adhering device is applicable as a table in the middle position when transferring wafer.

### TECHNICAL FIELD

The present invention relates to a fragile member processing system, and, in particular, to a fragile member processing system having a function to transfer a semiconductor wafer, for which a back side grinding process has been carried out, to a ring frame.

### BACKGROUND ART

Conventionally, for a semiconductor wafer (hereinafter, referred to as a “wafer”) having a circuit surface formed, the back side grinding process is carried out in a state that a protective sheet is stuck to the circuit surface; and then, a mounting process for integrating the wafer with a ring frame and a peeling process for peeling off the protective sheet from the wafer are carried out.

A wafer processing system for carrying out the mounting process and the peeling process is disclosed in, for example, Patent document 1. This wafer processing system is arranged to include a mounting device, which disposes the wafer on the side of the inner periphery of the ring frame and sticks a mount tape to these wafer and ring frame to integrate both into one body, and a peeling device, which adheres a peeling tape to the protective sheet stuck to the circuit surface side of the wafer and peels off the wafer form the protective sheet while pulling the peeling tape upward at an angle.
Patent document 1: Japanese Patent Application Laid-Open No. 2000-68293

### SUMMARY OF THE INVENTION

Problem to be solved by the Invention

The arrangement disclosed in the Patent document 1 allows the integration of the wafer and the ring frame to be carried out, i.e., the mounting process and the peeling process of the protective sheet to be carried out as a series of processes.

However, the thickness of the wafers to be required in these days becomes of order of several-tens μm, whereby in a state alone that the protective sheet is stuck to the circuit surface, the protective sheet cannot ensure the rigidity required for supporting the wafer during the grinding process, and therefore, the wafer is not able to be ground extremely thinly with the surface flatness thereof maintained. Also, the protective sheet is required to have a heat resistance and corrosion resistance because the surfacing process such as sputtering and metal deposition is performed for the back side of the wafer after grinding; however the fact is that the protective sheet formed of a resin cannot respond to such requests.

Thereupon, it prevails that a supporting plate such as a glass plate having certain rigidity or thickness is stuck to the circuit surface with a double-faced adhesive sheet interposed between them and by utilizing the rigidity or thickness of the supporting plate, the back side of the wafer is ground extremely thinly without giving any damage to the wafer.

However, when such an extremely thinned wafer is handled as on object, the apparatus disclosed in Patent document 1 cannot peel off the supporting plate form the wafer, whereby the wafer has to be peeled off from the supporting plate in another working step, which incurs the disadvantage that sequential operation of the process is disturbed, resulting in large reduction in working efficiency.

[Object of the Invention]

The present invention has been proposed in view of the above disadvantages, and an object thereof is to provide a fragile member processing system capable of carrying out a mounting step of integrating the fragile member such as the wafer with a holding member, a step of peeling off the supporting plate supporting the fragile member and transferring the fragile member to the holding member, and a step of peeling off the double-faced adhesive sheet from the fragile member as a series of processes

Another object of the present invention is to provide a fragile member processing system capable of processing even the object to be processed, in which only the protective sheet is stuck to the fragile member without using any supporting plate, employing the identical system.

Means for Solving Problems

To achieve the object, the present invention employs the arrangement in which a fragile member processing system, which handles a plate-like member, in which a fragile member is integrated with a supporting plate with a double-faced adhesive sheet interposed between them, as an object and peels off the fragile member from the supporting plate to transfer/adhere the fragile member to a predetermined holding member, comprises:

a mounting device which includes a mount table for supporting the holding member and supporting the object inside the holding member so as to expose a surface of the fragile member, and a sticking unit for sticking an adhesive tape to the surfaces of the holding member and the fragile member;

a transferring/adhering device which includes a first supporting member for supporting the supporting plate, a second supporting member for supporting the holding member at a position free of interference with the supporting plate, a peeling initiation portion forming device for forming a peeling initiation portion in a boundary portion between the supporting plate and the double-faced adhesive sheet, and a driving mechanism for moving the first and the second supporting members relatively to each other, thereby to initiate the peeling at the peeling initiation portion; and

a peeling device for peeling off the double-faced adhesive sheet on the fragile member transferred/adhered to the holding member.

The arrangement is preferably employed in which the first supporting member is arranged of a suction table for supporting the plate-like member, whereas the second supporting member is arranged of a pair of arms, which are positioned at the periphery of the suction table and are located at a position along the surface of the suction table as the initial position, and the arm is provided rotatably in a direction of allowing displacement by a predetermined angle from the initial position.

Also, it is possible that the suction table is liftably and lowerably provided, and lowers when the arm returns to the initial position from a position in which it has been erected, thereby to prevent the plate-like member and the fragile member from adhering again.

Further, the present invention may employ the arrangement in which a fragile member processing system, which uses an object to be processed having a supporting plate integrated by interposing a double-faced adhesive sheet between one surface of the fragile member and a supporting member, or an object to be processed having a protective sheet in which the protective sheet is provided on one surface of the fragile member, and transfers/adheres the fragile member to a holding member, thereby to perform a predetermined process, comprises:

a mounting device for disposing the object inside the holding member supported on a mount table in a state that the other surface of the fragile member is exposed, and sticking an adhesive tape to the surfaces of the fragile member and the holding member to integrate the object to be processed and the holding member;

a transferring/adhering device that has a function of, in a state that a peeling initiation portion has been formed between the fragile member and the supporting plate of the object having a supporting plate, peeling off the former from the latter to transfer/adhere the fragile member to the holding member, or a function of temporarily supporting the object having a protective sheet; and

a peeling device that peels off the double-faced adhesive sheet or protective sheet on the fragile member transferred/adhered to the holding member.

Further, the present invention is particularly applicable to a case of handling one, in which the fragile member is a semiconductor wafer and the supporting plate is a glass plate, as an object.

Further, the present invention may be arranged so as to include a detector for discriminating between the supporting plate and the protective sheet stuck to the object.

Effect of the Invention

According to the present invention, by incorporating the transferring/adhering device into the processing system including the device for mounting the fragile member onto the holding member, and the peeling device for peeling off the double-faced adhesive sheet or the protective sheet stuck to the fragile member, the applicable range of the object can be expanded to give generality to the processing system.

In the case of the object having only the protective sheet stuck to the surface of the fragile member, the transferring/adhering device can function as an intermediate table for transferring the object to the peeling device, whereby even when the fragile member is not supported by a supporter, the application of the present invention is not hindered, and in this point also, the generality can be given. In this moment, in a case where the detector is provided, it is determined on the device side whether the object includes the supporting plate or the protective sheet, and in a case where the object includes the protective sheet, the transferring/adhering device may be used as an intermediate table for transferring the object without driving it.

### BRIEF DESCRIPTION OF THE DRAWINGS

FIG. 1 is a schematic perspective view showing an entire arrangement of a wafer processing system.

FIG. 2 is a sectional view showing a series of steps in which an object to be processed is transferred/adhered to a ring frame.

FIG. 3 is a schematic perspective view showing an alignment device and peripheral devices thereof.

FIG. 4 is a schematic perspective view of a mounting device.

FIG. 5 is a schematic perspective view of a transferring/adhering device.

FIG. 6 is a schematic perspective view showing a state that the transferring/adhering device transfers/adheres a wafer to the ring frame.

FIG. 7 is a schematic perspective view of a tape peeling device.

FIGS. 8(A) to (C) are views for explaining the operation until the step in which a chuck nips a peeling tape.

FIGS. 9(A) to (C), which shows the operation following that shown in FIG. 8(C), are views for explaining the operation until the step in which a double-faced adhesive sheet is peeled off from the wafer.

### EXPLANATION OF REFERENCE NUMERALS

10 Wafer processing system
17 Mounting device
20 Transferring/adhering device
21 Peeling device
40 Mount table
41 Sticking unit
60 Suction table (first supporting member)
61 Arm (second supporting member)
62 Peeling initiation portion
63 Peeling initiation portion forming device
64 Driving mechanism
A First object to be processed
DT Dicing tape (adhesive tape)
RF Ring frame (holding member)
P Glass plate (supporting plate)
S Double-faced adhesive sheet
W Semiconductor wafer (fragile member)
PT Protective tape

### PREFERRED EMBODIMENTS FOR WORKING THE INVENTION

Hereinafter, embodiments of the present invention will be described with reference to the accompanied drawings.

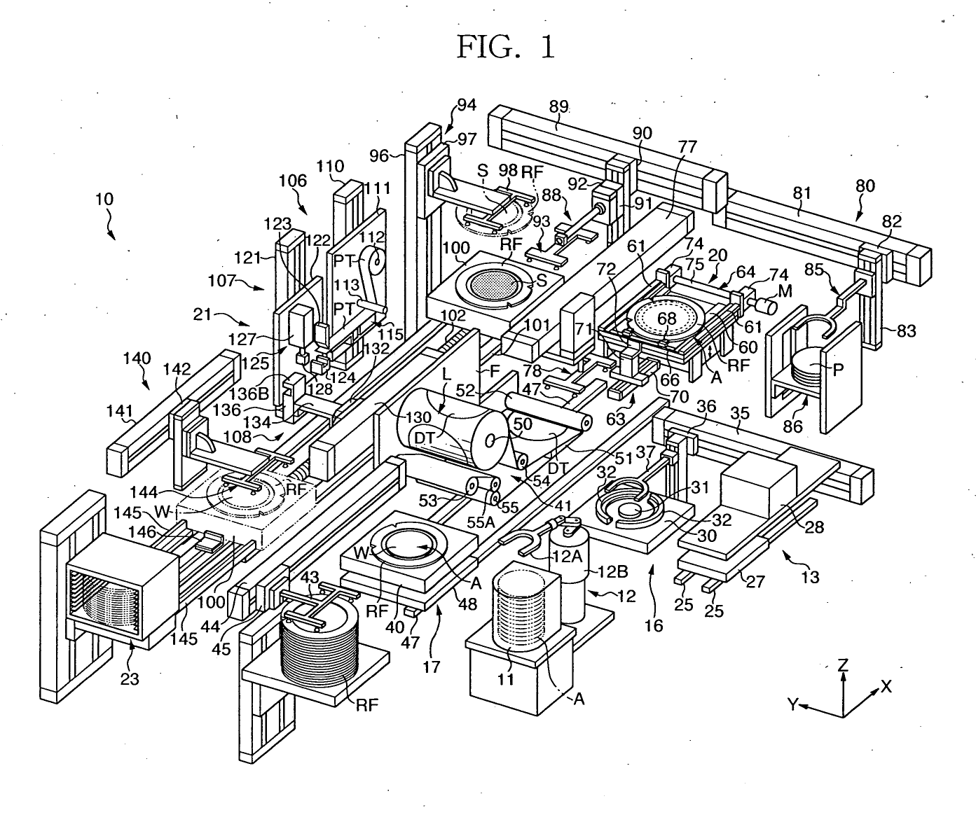

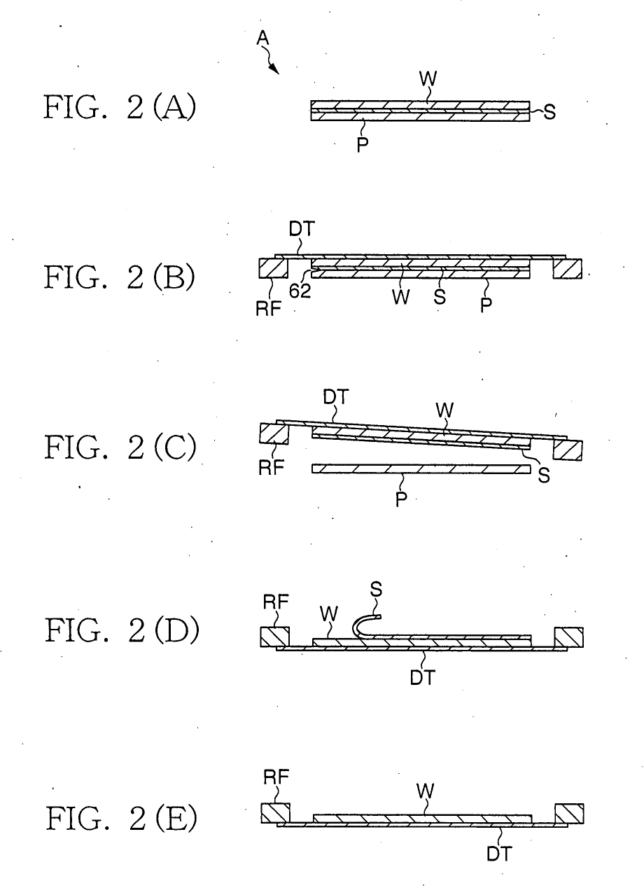

FIG. 1 is schematic perspective view showing a fragile member processing system in accordance with the present invention applied to a wafer processing system. FIG. 2 shows sectional views illustrating the processing steps of the wafer in a time-series manner. Here, in an object A to be processed in this embodiment, as shown in FIG. 2(A), a glass plate P as a supporting plate is adhered to the circuit surface (lower surface in FIG. 2(A)) side of a wafer W as a fragile member with a double-faced adhesive sheet S having a ultraviolet curable type adhesive interposed. The double-faced adhesive sheet S in this embodiment has a three-layered structure including the ultraviolet curable type adhesive on one surface of a base sheet and the adhesive having week adhesive strength on the other surface. As shown in FIG. 2(B), the object A to be processed is integrated with a dicing tape DT constituting the adhesive tape interposed in a state that the wafer W is disposed inside the inner periphery of the ring frame RF as a holding member. Then, the process is performed in which as shown in FIG. 2(C), the glass plate P is peeled off at the boundary face between the double-faced adhesive sheet S and the glass plate P; and then, as shown in FIG. 2(D), the double-faced adhesive sheet S remaining on the circuit surface side of the wafer W is peeled off from the wafer W; and finally, only the wafer W is left inside the ring frame RF (refer to FIG. 2(E)).

Referring to FIG. 1, a wafer processing system 10 is arranged to include an ultraviolet irradiation device 13 which takes out the objects A stored in a magazine 11 one by one via a robot arm 12 and cures the ultraviolet curable adhesive layer of the double-faced adhesive sheet S; an alignment device 16 which transfers and positions the object A after ultraviolet irradiation by the ultraviolet irradiation device 13, a mounting device 17 which integrates the object A with the ring frame RF; a transferring/adhering device 20 which peels off the glass plate P from the object A and transfers/adheres the wafer W to the ring frame RF; a peeling device 21 which peeling off the double-faced adhesive sheet S remaining on the circuit surface side of the wafer W; and a stocker 23 which stores the wafer W in a state that the wafer from which the double-faced adhesive sheet S has been peeled off is supported by the ring frame RF.

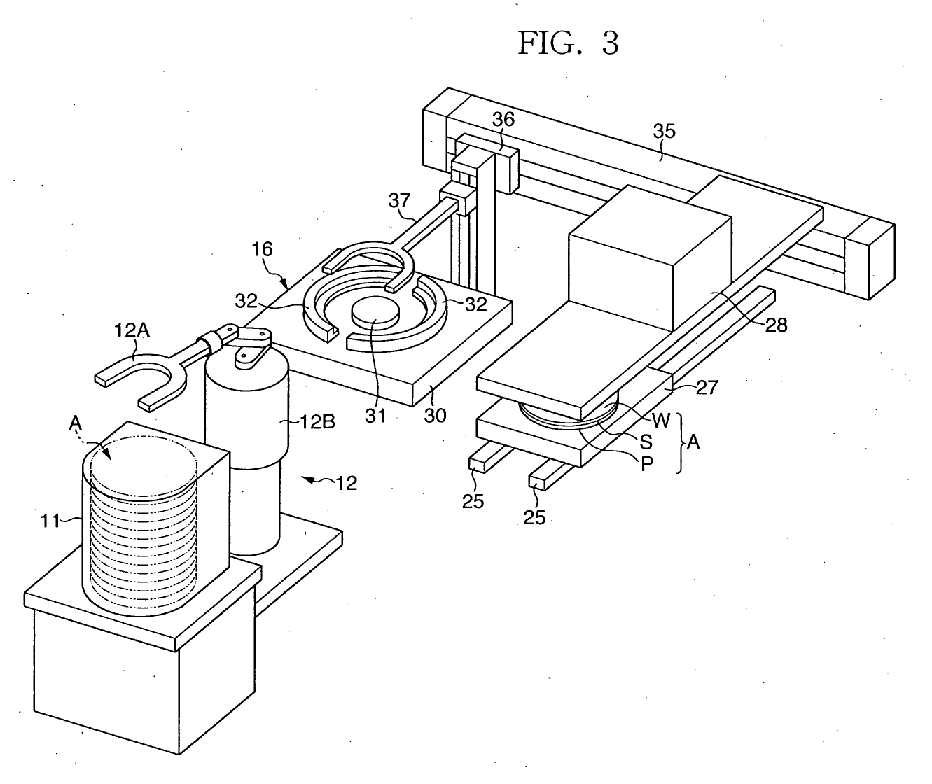

As shown in FIG. 3, many objects A are stored in the magazine 11 in a multi-step manner with the back side of the wafer W oriented upward in a state that they are kept in a substantially horizontal posture. The robot arm 12 for taking out the object A from the magazine 11 includes a multi-joint arm section 12A and a lifter 12B that supports the multi-joint arm section 12A. The multi-joint arm section 12A is arranged so that the tip side thereof is formed in a bifurcated shape, and the tip portion of its bifurcated side has a sucking portion (not shown). Thereby, the object A, is sucked on the back side (upper surface side) and transferred to the ultraviolet irradiation device 13, and in addition hereto, the object A positioned by the alignment device 16 is sucked and transferred to the mounting device 17.

The ultraviolet irradiation device 13 includes a slide table 27 movable along a pair of guide rails 25 and 25 disposed substantially parallel to each other, and an ultraviolet irradiation section 28, which is located above the slide table 27. The slide table 27 moves along the guide rails 25 with the object A placed thereon, and owing to this, the ultraviolet curable adhesive layer side of the double-faced adhesive sheet S is cured to prepare for the peeling operation, which will be described later.

The alignment device 16 is arranged of a plate member 30 having a substantially square shape viewed from the top, a center table 31 provided in the center of the plate member 30 and a pair of convexities 32 and 32 which are supported by the plate member 30 and are provided to close and away form each other in the plane surface, and yet assume a substantially semicircular arc viewed from the top. The center table 31 is provided rotatably within a substantially horizontal plane, the positioning for specifying the crystal orientation of the wafer W is carried out by rotating the object A using a camera or the like (not shown), and in addition hereto, the centering of the wafer W can be performed by making the convexities 32 and 32 come closer to each other. A slider 36 movable via a rod-less cylinder 35 and a suction arm 37, which is liftably and lowerably supported by the slider 36 and has a bifurcated portion on the tip side thereof, are provided in the side position of the alignment device 16 and the ultraviolet irradiation device 13, and the suction arm 37 sucks and transfers the object A from the ultraviolet irradiation device 13 to the alignment device 16.

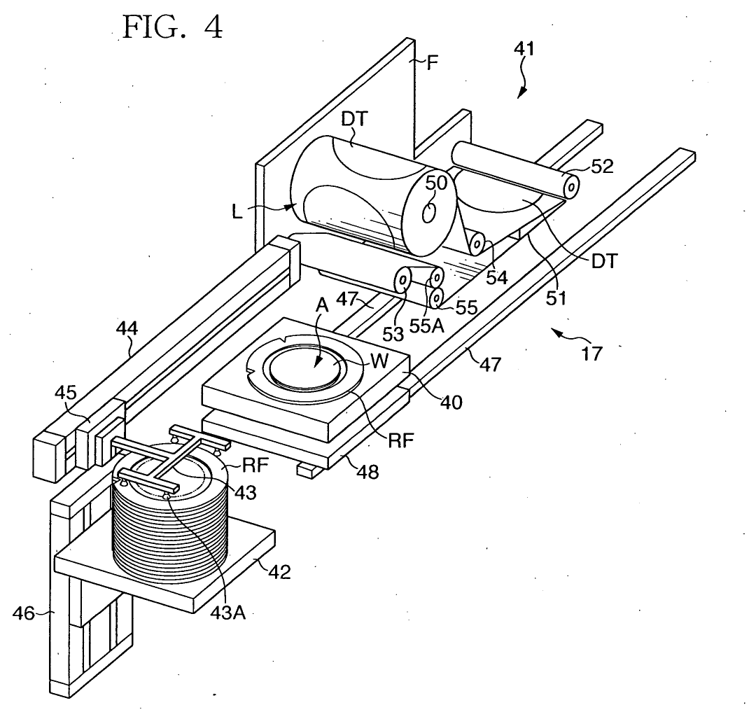

As shown in FIG. 1 and FIG. 4, the mounting device 17 is arranged to include a mount table 40 for supporting the ring frame RF and the object A and a sticking unit 41 for sticking a dicing tape DT to integrate the ring frame RF and the object A into one body. The ring frames RF are stocked on a stock table 42 disposed on the side of the mount table 40 in a state of being piled up. The uppermost ring frame RF is transferred to the mount table 40 by the transfer arm 43 provided with a sucking portion 43A. A movable slide block 45 supports the transfer arm 43 via a uniaxial robot 44. Also, the stock table 42, which is liftably and lowerably supported by a lift robot 46, is adapted to lift by a distance equal to the thickness of the ring frame RF whenever the sucking portion 43A of the transfer arm 43 sucks and transfers the ring frame RF.

The mount table 40 is liftably and lowerably provided on a slide base 48 provided movably along a pair of guide rails 47 and 47, and is provided so that it can go up to a height position in which the ring frame RF is received when the transfer arm 43 is positioned above the mount table 40.

The sticking unit 41 is for sticking the dicing tape DT to the ring frame RF and the back side (upper surface in the figures) of the wafer W. As for the dicing tape DT in this embodiment, the laminate obtained by sticking a belt-shape release liner to one surface of the resin tape assuming a belt shape is employed as a web sheet L, and by forming a cut having a closed-loop shape within the surface of the resin tape in the web sheet L, a dicing tape DT having a substantially circular shape viewed from the top is formed at each predetermined interval. The sticking unit 41 is arranged of a plate-like frame F, which is substantially upstanding; a feed-out roll 50, which is supported rotatably within the surface of the frame F, and supports the web sheet L feedably while imparting a predetermined tension to the web sheet L via a torque motor (not shown) provided on the back of the frame F; a peel plate 51 for peeling off the dicing tape DT by sharply inverting the feeding direction of the fed-out web sheet L; a press roll 52 disposed along the tip edge of the peel plate 51; a drive roll 55 for imparting a winding force to the web sheet L; a nip roll 55A for inserting the web sheet L under the drive roll 55; a winding roll 53 for fixing the lead end of the web sheet L in which the dicing tape DT has been peeled off to wind the same; and a guide roll 54 disposed in the way of the feed-out path. Additionally, the winding roll 53 is connected to the output shaft of a motor of the drive roll 55 (not shown) provided on the back side of the frame F via a pulley, and is arranged so that the web sheet L, of which the dicing tape DT has been peeled off, can be wound without slacking via a sliding belt.

As shown in FIGS. 1, 5 and 6, the transferring/adhering device 20 is arranged to include a suction table 60 as a first supporting member for supporting the glass plate P of the object A; a pair of arms 61 and 61 as a second supporting member for supporting the ring frame RF at a position where the arms do not interfere with the glass plate P; a peeling initiation portion forming device 63 which forms a peeling initiation portion 62 (refer to FIG. 2(B)) in a boundary portion between the glass plate P and the ultraviolet cured adhesive layer of the double-faced adhesive sheet S; and a driving mechanism 64 for moving the suction table 60 and the arms 61 and 61 relatively to each other to initiate the peeling of the glass plate P from the double-faced adhesive sheet S at the peeling initiation portion 62.

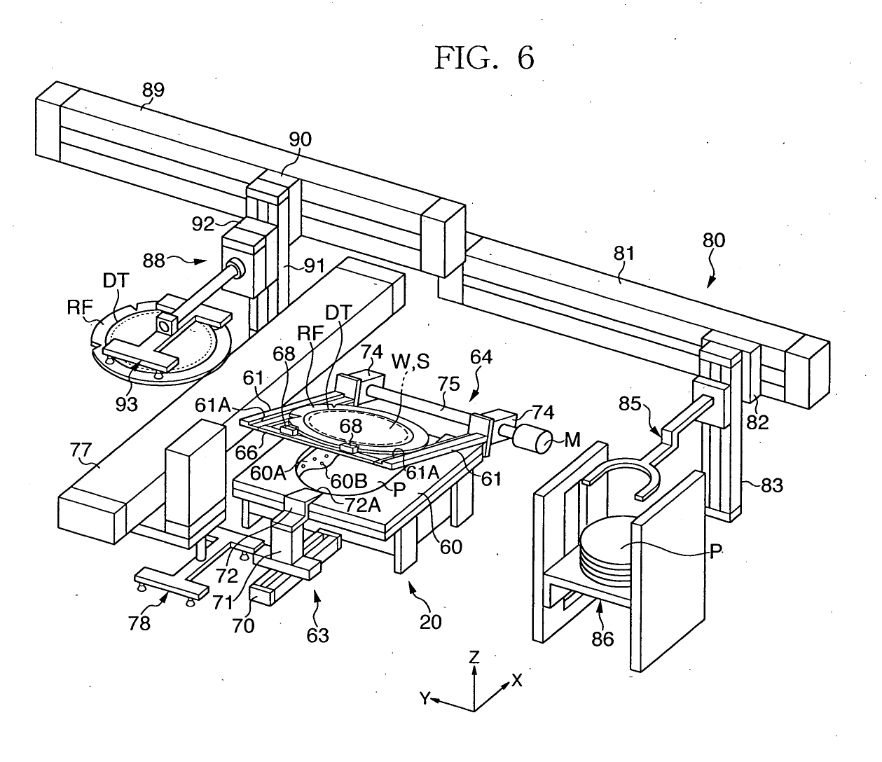

As shown in FIG. 6, the suction table 60 has an upper surface provided with a concavity 60A having a substantially U-letter shape viewed from the top in the central area thereof. A circular arc of the U-letter portion, which is provided in a substantially same shape as the peripheral shape of the glass plate P, allows the positioning in the X-direction of the object A to be made when the ring frame RF is placed on the arms 61, and the glass plate P is slid in the circular arc direction of the U-letter in a manner of pressing it. Also, many suction holes 60B are provided in the bottom face of the concavity 60A. The concavity 60 is arranged so that the depth of thereof is set to coincide with the thickness of the glass plate P and owing to this, the peeling initiation portion 62 can be formed in an upper surface portion of the glass plate P; i.e., in the peripheral portion of the boundary face with the ultraviolet cure adhesive layer of the double-faced adhesive sheet S. Additionally, the suction table 60 is liftably and lowerably provided via a lift device (not shown), and by temporarily lowering the suction table 60, the wafer W and the glass plate P are held so that, after the wafer is peeled from the glass plate, the double-faced adhesive sheet S of the wafer W and the glass plate P do not adhere to each other again.

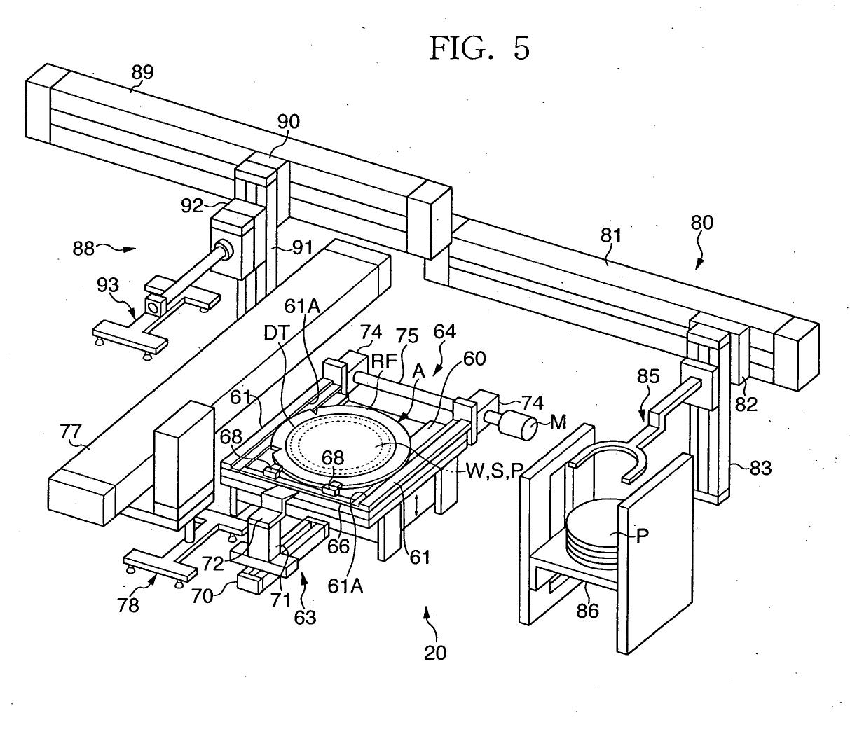

Steps 61A and 61A are formed respectively for the pair of arms 61 and 61 to control the shift in the Y direction at the time of placing the ring frame RF thereon. A link bar 66 is provided on the one-end sides of the arms 61 and 61; i.e., between one-end portions at the front of the left side in FIG. 5, and this link bar 66 is provided with two chucking members 68 and 68 capable of holding the ring frame RF so as to control the movement thereof.

As shown in FIG. 6, the peeling initiation portion forming device 63 is arranged of a uniaxial robot 70, a stand block 71 movable along the uniaxial robot 70 and a blade member 72 attached to the upper end of the stand block 71. The tip side of the blade member 72 is provided advanceably and retreatably along the upper surface of the suction table 60 by causing the stand block 71 to move along the uniaxial robot 70. Owing to this, when a tip blade 72A of the blade member 72 advances toward the center of the suction table 60, the tip blade 72A enters the peripheral edge of the glass plate P and the double-faced adhesive tape S and forms a slit in the boundary portion between the glass plate P and the ultraviolet cured adhesive layer of the double-faced adhesive tape S, and resultantly, the slit is formed as the peeling initiation portion 62.

The driving mechanism 64 is arranged of a rotary shaft 75, which extends through blocks 74 and 74 provided at the end of the pair of the arms 61 and 61 and is supported by a support frame (not shown), and a motor M for rotating the rotary shaft 75 circularly, and owing to the drive by the motor M, the arms 61 and 61 are rotatable with the rotary shaft 75 assumed to be a center of the rotation, and one end on the side having the link bar 66 equipped assumed to be a free end. That is, the arms 61 and 61 are rotatably provided between the initial position where the arms are held substantially horizontally and the position where the free end lifts and the entirety of the arm 61 is erected.

A transfer arm 78, which is movable by a uniaxial robot 77, is provided in the side position between the transferring/adhering device 20 and the mounting device 17, and this transfer arm 78 is arranged to suck and transfer the object A integrated with the ring frame RF via the dicing tape DT to the transferring/adhering device 20.

A glass plate-removing device 80 is provided in the right area of the transferring/adhering device 20 in FIG. 6. This glass plate-removing device 80 is arranged of a slider 82, which is movable along a cylinder 81 extending in the Y-axis direction, a suction arm 85 supported via a Z-axis cylinder 83 provided on the slider 82, and a lift type collection table 86, which is capable of collecting the glass plates P while piling them up in a multi-step manner.

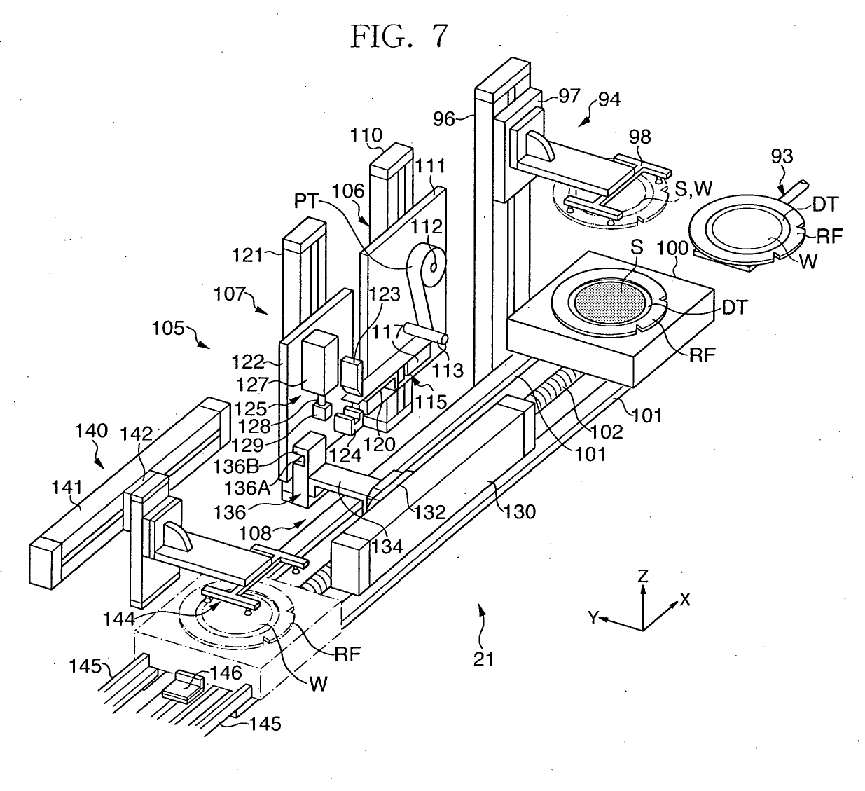

As shown in FIG. 1 and FIG. 6, the wafer W, from which the glass plate P has been peeled off by the transferring/adhering device 20 and which has been transferred/adhered to the ring frame RF, is transferred to the peeling device 21 side via a reversing/transferring device 88. This reversing/transferring device 88 is arranged of a uniaxial robot 89 disposed along the Y-axis direction, a lift uniaxial robot 91 supported by slider 90 that moves along the uniaxial robot 89, a lift slider 92 that moves along the lift uniaxial robot 91, and a reversing/suctioning arm 93 rotatably supported by the lift slider 92. The reversing/suctioning arm 93 is arranged so as to suck the ring frame RF on an upper surface, and then to turn it substantially 180° so that the upper surface of the wafer W is exposed, and in this state, the wafer W is delivered to a neighboring receiving device 94 shown in FIG. 7.

As shown in FIG. 1 and FIG. 7, the receiving device 94 includes a Z-axis uniaxial robot 96, a slider 97 supported by the Z-axis uniaxial robot 96 and a lift suction arm 98 supported by the slider 97. As described above, the lift suction arm 98 is adapted to suck and receive the ring frame RF portion, which has been reversed upside down, from the reversing suction arm 93, and to transfer the frame to a peeling suction table 100 constituting the peeling device 21.

As shown in FIGS. 7 to 9, the peeling device 21 is arranged of a pair of guide rails 101 and 101, which support the peeling suction table 100 movably along the X-axis direction, a feed screw shaft 102, which is disposed between the guide rails 101, and extends through a nut member (not shown) located on the lower surface side of the peeling suction table 100, and a peeling unit 105 for peeling off the double-faced adhesive sheet S remaining on the upper surface side of the wafer W.

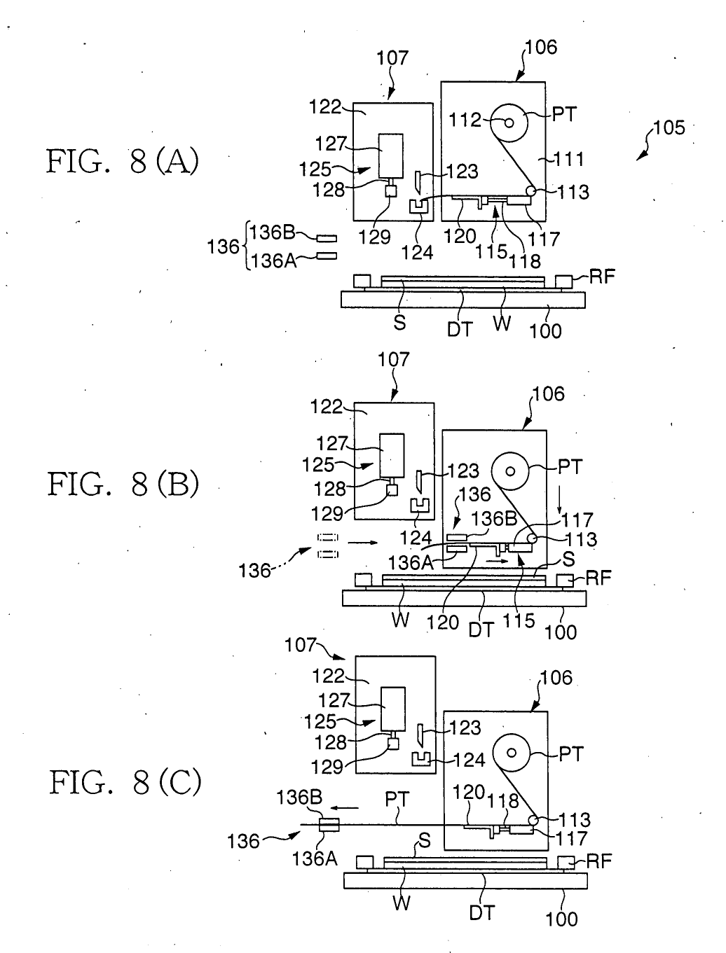

The peeling unit 105 is arranged of a peeling tape feeder 106, a peeling tape adhering section 107 and a peeling tape pulling section 108. The peeling tape feeder 106 is arranged of a first lift plate 111 supported liftably and lowerably along a first cylinder 110 extending in the Z-axis direction, a support roll 112, which is disposed within the surface of the first lift plate 111 and supports a peeling tape PT wound in a roll shape, a guide roll 113 for the peeling tape PT and a guide member 115 for guiding the peeling tape PT in a substantially horizontal posture. As shown in FIG. 8, the guide member 115 includes a bracket 120 having a substantially L-letter shape connected to a piston rod 118 of a horizontal cylinder 117, and the bracket 120 is provided so that the longer piece side thereof is positioned in a substantially horizontal plane to guide the peeling tape PT on the upper surface side.

The peeling tape adhering section 107 is arranged of a second cylinder 121 extending in the Z-axis direction, a second lift plate 122 supported liftably and lowerably by the second cylinder 121, a cutter blade 123 disposed within the surface of the second lift plate 122, a cutter receiver 124 positioned below the lower portion of the cutter blade 123 and a welding unit 125 provided in a position neighboring the cutter blade 123. The cutter receiver 124 is supported positionably with respect to the surface of the second lift plate 122 by a cylinder (not shown) provided on the back side of the second lift plate 122 and in addition hereto, the cutter blade 123 is advanceably and retreatably provided with respect to the cutter receiver 124. The welding unit 125 includes a heat block 129 at the lower end of a piston rod 128 extending downward from the lower end of the cylinder body 127; and the heat block 129 is arranged so as to weld the peeling tape PT to the double-faced adhesive sheet S on the wafer W.

The peeling tape pulling section 108 includes a cylinder 130 along the guide rail 101 at a position in which it faces the peeling tape feeder 106 and the peeling tape adhering section 107, a slider 132, which moves along the cylinder 130, and a chuck 136 provided on the tip of an arm 134 supported by the slider 132. The chuck 136, which has a lower jaw 136A and an upper jaw 136B, is arranged so that by closing the gap between the lower jaw 136A and the upper jaw 136B, the peeling tape PT is nipped and held therebetween. Therefore, after the chuck 136 nips the peeling tape PT, and one part of the peeling tape PT is welded to the double-faced adhesive sheet S, by moving the chuck 136 rightward in FIG. 7, the double-faced adhesive sheet S is pulled and gradually peeled off from the surface of the wafer W. Additionally, the peeling double-faced adhesive sheet S is thrown away into a waste box (not shown).

As shown in FIG. 7, a final transferring device 140 is disposed on the side of the peeling tape adhering section 107. The final transferring device 140 includes a cylinder 141 extending in the X-axis direction, a slider 142 supported by the cylinder 141 and a suction arm 144 supported liftably and lowerably on the slider 142. The suction arm 144 is adapted so as to suck the ring frame RF on the peeling suction table 100, which has moved downward, and to transfer the wafer W integrated with the ring frame RF between a pair of path-forming members 145 and 145 assuming an L-letter shape in section positioned on the extended line of the guide rail 101. The ring frame RF transferred between the path-forming members 145 is arranged so that it is stored in the stocker 23 by means of a kicker 146 disposed between the path-forming members 145.

Next, the entire operation of the wafer processing system 10 in accordance with the embodiment of the present invention will be described.

The objects A stored in the magazine 11 are taken out one by one by the robot arm 12 and transferred to the ultraviolet irradiation device 13. In the ultraviolet irradiation device 13, by irradiating ultraviolet rays through the glass plate P of the object A, the ultraviolet curable adhesive layer of the double-faced adhesive sheet S is cured to prepare for the peeling in the following steps.

The object A for which the ultraviolet irradiation has been made is transferred to the alignment device 16 by the suction arm 37, and the crystal orientation is specified and aligned in the alignment device 16. The aligned object A is transferred to the mount table 40 of the mounting device 17 via the robot arm 12. Here, the ring frame RF has been transferred in advance to the mount table 40 by the operation of the transfer arm 43.

The dicing tape DT, which is sequentially peeled off at the tip position of the peel plate 51 when the mount table 40 moves in the direction where it passes under the sticking unit 41 of the dicing tape DT, is stuck to the upper surface side of the object A and the ring frame RF transferred to the mount table 40 by receiving a press force by the press roll 52, and this allows the object A and the ring frame RF to be integrated into one body.

The object A and the ring frame RF integrated into one body as described above are sucked/held, at the moment that the mount table 40 moves to the transferring/adhering device 20 side, by the transfer arm 78, which waits in the position above it, and are transferred to the transferring/adhering device 20. In the state that the transfer has completed, the glass plate P is received in the concavity 60A provided in the central area of the suction table 60 of the transferring/adhering device 20 and is sucked/held, whereas the ring frame RF is received within the steps 61A and 61A formed in each inside of the arms 61 and 61. In this state, the chucking member 68 provided on the link bar 65 side nips the periphery of the ring frame RF. Then, the peeling initiation portion forming device 63 is activated and the blade member 72 advances toward the center of the object A along the upper surface of the suction table 60, the tip blade 72A enters the boundary face by a predetermined amount in the peripheral rib of the glass plate P and the ultraviolet curable adhesive layer of the double-faced adhesive sheet S, and thereby, the slit is formed and the peeling initiation portion 62 is formed owing to the slit.

Then, the motor M of the driving mechanism 64 is activated, and the free end of the pair of arms 61 and 61 rotates upward away from the suction table 60 to change its angle in the erection direction from the initial horizontal position. As the amount of the changed angle increases, the adherence area of the glass plate P and the double-faced adhesive sheet S decreases gradually, and when the arm 61 rotates to a predetermined erection angle, for example, to substantially 45° or so, the adherence area of both becomes zero, whereby the wafer W is peeled off completely from the glass plate P along with the double-faced adhesive sheet S, and the wafer W results in being transferred to the ring frame RF.

When the peeling has completed, the arms 61 and 61 return to the initial horizontal posture. At this time, the suction table 60 lowers in the direction that the position of the upper surface becomes slightly lower, and is held to prevent the double-faced adhesive sheet S existing on the lower face side of the wafer W from adhering to the glass plate P again. The ring frame RF returned to the initial horizontal posture and the wafer W transferred and integrated therewith are sucked/held by the reversing/suction arm 93 of the reversing/transferring device 88, and are sucked/held by the lift suction arm 98 on the peeling device 21 side in a state that the positions of the upper and lower surfaces are reversed 180°, and transferred to the peeling table 100. Accordingly, the wafer W on the peeling table 100 comes into a state that the double-faced adhesive sheet S is positioned on the upper surface side. Additionally, after the ring frame RF has been transferred along with the wafer W, the state that the glass plate P is left on the suction table 60 of the transferring/adhering device 20 is generated; however the glass plate P is sucked by the suction arm 85 of the glass plate-removing device 80 and stored by the collection table 86.

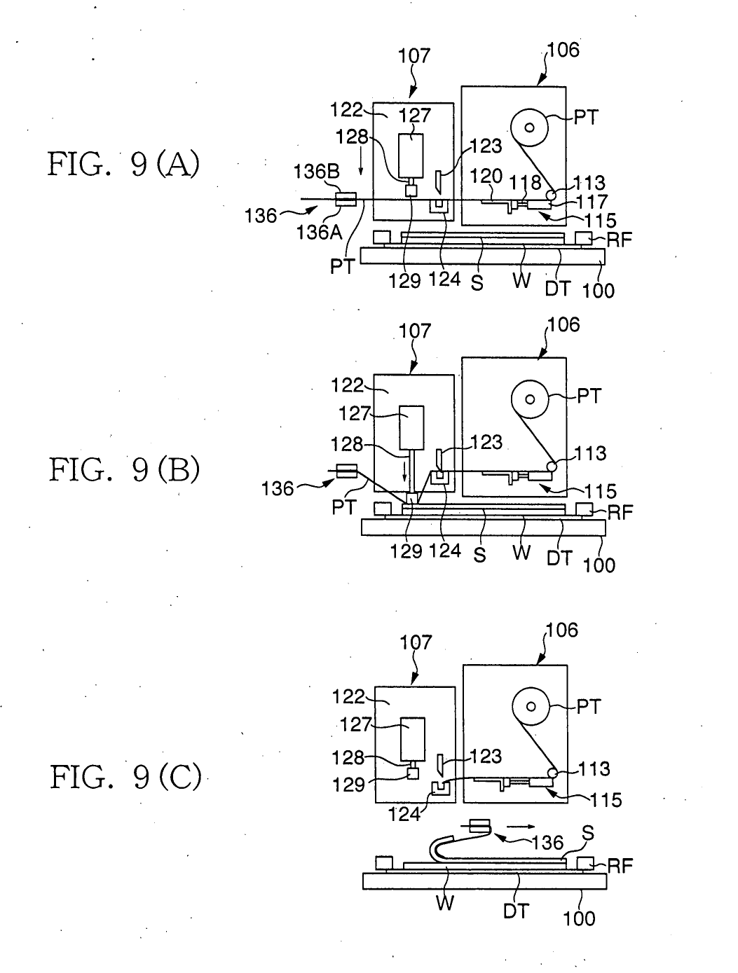

The double-faced adhesive sheet S on the wafer W transferred/adhered to the ring frame RF is peeled off when the peeling table 100 passes below the peeling device 21. That is, as shown in FIG. 8(A), when the peeling table 100 moves below the peeling unit 105, the peeling tape feeder 106 lowers, and the chuck 136 moves toward the lead end of the peeling tape PT by the operation of the cylinder 130 and nips and holds the lead end between the upper side and the lower side (refer to FIG. 8(B)). After that, when the chuck 136 returns to the opposite side and pulls out the peeling tape PT by a predetermined amount (refer to FIG. 8(C)), the peeling tape adherence section 107 lowers (refer to FIG. 9(A)). The cutter receiver 124 is held at a position of going backward from the surface of the second lift plate 122 at the moment of this lowering, and moves so that it protrudes in the near side from the surface of the second lift plate 122 by the drive of a cylinder (not shown) when receiving a signal indicating that the second lift plate 122 has reached the lowering end. Accordingly, no positional interference with the peeling tape PT occurs.

Then, the heat block 129 of the welding unit 125 lowers, one part of the peeling tape PT is welded to the peripheral portion of the double-faced adhesive sheet S, and the tip of the cutter blade 123 enters the cutter receiver 124, thereby to cut the peeling tape PT off (refer to FIG. 9(B)). After the peeling tape feeder 106 and the peeling tape adherence section 107 rise, and the traveling space for the chuck 136 is formed, the chuck 136 moves rightward in FIG. 9(C) while holding the peeling tape PT, thereby allowing the double-faced adhesive sheet S to be peeled off from the wafer W.

The wafer W from which the double-faced adhesive sheet S has been peeled off is sucked along with the ring frame RF and stored in the stocker 23, and after the amount of the wafers W have reached a predetermined stock amount, the post-processes such as dicing and die bonding are carried out.

Accordingly, according to the embodiment as described above, even when the glass plate P is used to grind the wafer W extremely thinly, the peeling can be carried out in the way of a series of processes, and the off-line work using a separate transferring/adhering device is not required differently from the conventional case, thereby enabling the entire process to be carried out efficiently.

As described above, the best arrangement, method and the like for carrying out the present invention have been disclosed in the above description; however, the present invention is not limited to the above description.

That is, the present invention has been particularly illustrated and described for the specific embodiment; however, it is possible for a person skilled in the art to add various modifications to the above described embodiment, if necessary, with respect to shape, position, disposition or the like without departing from the range of the technical spirit and object of the present invention

For example, in the embodiment described above, as the object A, the object having a supporting plate in which the glass plate P has been stuck to the circuit surface side of the wafer W with the double-faced adhesive sheet S interposed between them is given; however, the present invention is applicable to the object having no glass plate P as well. That is, the present invention is applicable to the object having a protective sheet, in which only the protective sheet is stuck to the circuit surface side of the wafer W. In this case, the transferring/adhering device 20 may be used as an intermediate table in transferring the wafer W integrated with the ring frame RF to the peeling table 100. In such a case, it is preferred to provide the detector for determining whether the object includes the supporting plate or the protective sheet. As for the detector, are exemplified a limited reflection sensor, a mass measurer, a mark-detecting sensor, etc., which can be provided in the slide table 27 of the ultraviolet irradiation section 28, the center table 31 of the alignment device 16 or the mount table 40 of the mounting device 17. Here, in the case of the limited reflection sensor, by setting the sensor to the reflection distance from the wafer W having the glass plate P provided, an NG signal is outputted with respect to the object of which the reflection distance is different from it, whereby, in this case, it is enough that the program is set so as to let the signal pass without driving the driving mechanism 64 of the transferring/adhering device 20. In the case of the mark-detecting sensor, the sensor may be set to detect the marks affixed to the glass plate P.

In the above embodiment, the case in which the fragile member is a semiconductor wafer W is given; however, the present invention may be applied also to the case where another fragile plate-like member is transferred/adhered.

1. A fragile member processing system, which handles a plate-like member, in which a fragile member has been integrated with a supporting plate with a double-faced adhesive sheet interposed, as an object to be processed, and which peels off the fragile member from the supporting plate and transfers the fragile member to a predetermined holding member, comprising:
a mounting device which includes a mount table for supporting the holding member and supporting the object to be processed inside the holding member so as to expose a surface of the fragile member, and a sticking unit for sticking an adhesive tape to the surfaces of the holding member and the fragile member;
a transferring/adhering device which includes a first supporting member for supporting the supporting plate, a second supporting member for supporting the holding member at a position free of interference with the supporting plate, a peeling initiation portion forming device for forming a peeling initiation portion in a boundary portion between the supporting plate and the double-faced adhesive sheet, and a driving mechanism for moving the first and the second supporting members relatively to each other, thereby to initiate the peeling at the peeling initiation portion; and
a peeling device for peeling off the double-faced adhesive sheet from the fragile member transferred/adhered to the holding member.

2. The fragile member processing system according to claim 1, wherein the first supporting member is arranged of a suction table for supporting the plate-like member;
the second supporting member is arranged of a pair of arms, which are positioned at the peripheral side of the suction table and are located at a position along the surface of the suction table as the initial position; and
the arm is provided rotatably in a direction of allowing displacement by a predetermined angle from the initial position.

3. The fragile member processing system according to claim 2, wherein the suction table is liftably and lowerably provided, and lowers when the arm returns to the initial position from a position in which it has been erected, thereby to prevent the plate-like member and the fragile member from adhering again.

4. A fragile member processing system, which uses an object to be processed having a supporting plate integrated by interposing a double-faced adhesive sheet between one surface of the fragile member and a supporting member, or an object to be processed having a protective sheet in which the protective sheet is provided on one surface of the fragile member, and transfers/adheres the fragile member to a holding member, thereby to perform a predetermined process, comprising:
a mounting device for disposing the object to be processed inside the holding member supported on a mount table in a state that the other surface of the fragile member is exposed, and sticking an adhesive tape on the surfaces of the fragile member and the holding member to integrate the object to be processed and the holding member;
a transferring/adhering device that has a function of, in a state that a peeling initiation portion has been formed between the fragile member and the supporting plate of the object to be processed having a supporting plate, peeling off the former from the latter to transfer/adhere the fragile member to the holding member, or a function of temporarily supporting the object to be processed having a protective sheet; and
a peeling device that peels off the double-faced adhesive sheet or protective sheet on the fragile member transferred/adhered to the holding member.

5. The fragile member processing system according to any one of claim 1 to claim 4, wherein the fragile member is a semiconductor wafer, and the supporting plate is a glass plate.

6. The fragile member processing system according to claim 4, further comprising a detector for discriminating between the supporting plate and the protective sheet stuck to the object to be processed.

7. The fragile member processing system according to claim 5, further comprising a detector for discriminating between the supporting plate and the protective sheet stuck to the object to be processed.
